(19) United States
(12) Patent Application Publication
(10) Pub. No.: US 2014/0177262 A1
(43) Pub. Date: Jun. 26, 2014

(54) LIGHT SOURCE AND LIGHT EMITTING DIODE AUTOMOBILE LAMP HAVING THE LIGHT SOURCE

(71) Applicant: HON HAI PRECISION INDUSTRY CO., LTD., New Taipei (TW)

(72) Inventor: CHIH-CHEN LAI, New Taipei (TW)

(21) Appl. No.: 13/926,117

(22) Filed: Jun. 25, 2013

(30) Foreign Application Priority Data
Dec. 24, 2012 (TW) 101149419

(51) Int. Cl. H01L 33/50; F21S 8/10

(52) U.S. Cl. CPC H01L 33/50; F21S 48/00
USPC 362/555; 257/98

(57) ABSTRACT

A light source includes a light emitting diode (LED) packing structure, a fiber and a light color converting portion. An end of the fiber couples with the LED packing structure. The light color converting portion is arranged at an opposite end of the fiber. The light color converting portion contains phosphor therein. Blue light emitted by the LED package transmits to the light color converting portion via the fiber and excites the phosphor to produce yellow light which mixes with the blue light to generate white light. An LED automobile lamp having the light source is also provided.

### BACKGROUND

1. Technical Field

The present disclosure generally relates to semiconductor lamps, and particularly to a light source and a light emitting diode (LED) automobile lamp having the light source.

2. Description of the Related Art

LEDs have many advantages, such as high luminosity, low operational voltage, low power consumption, compatibility with integrated circuits, faster switching, long term reliability, and environmental friendliness which have promoted their wide use as a light source.

A conventional LED automobile lamp includes an LED light source, a reflecting shell, a shading portion and a lens. The LED light source includes an LED die and an encapsulation layer with phosphor to cover the LED die. Blue light generated by the LED die excites the phosphor in the encapsulation layer to form yellow light which mixes with the blue light to produce white light. The white light is reflected by the reflecting shell and converged to the shading portion. The white light is regulated to a preset luminance shape and radiate to ambient environment through the lens. However, the blue light generated by the LED die has different brightness and intensities in different radiation angles, whereby the resultant white light has different hues, for example, blue-white at a center of the white light and yellow-white at a periphery of the white light. The white light cannot have a uniform hue, which is undesirable for lighting. Moreover, heat generated by the LED die influences a stability of the phosphor contained in the encapsulation layer and the LED die itself, which leads to a decay of the white light emitting LED. In addition, the heat can also affect the quality of the lens and the components of the car around the LED automobile lamp.

Therefore, it is desirable to provide an LED automobile lamp which can overcome the above-described problems.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present LED automobile lamp. Moreover, in the drawings, all the views are schematic, and like reference numerals designate corresponding parts throughout the views.

FIG. 1 is a schematic view of an LED automobile lamp in accordance with an exemplary embodiment of the present disclosure.

FIG. 2 is a cross-sectional view of an LED package of the LED automobile lamp of FIG. 1.

FIG. 3 is a schematic view of the LED package, a fiber and a light color converting portion of the LED automobile lamp of FIG. 1, which are assembled together.

### DETAILED DESCRIPTION

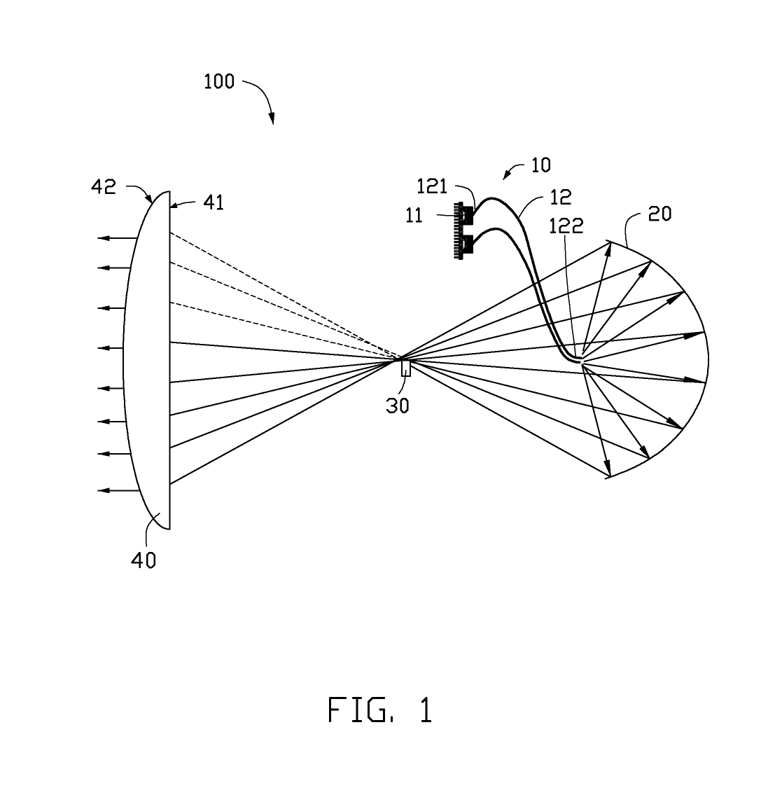

Referring to FIG. 1, an LED automobile lamp 100 in accordance with an embodiment is provided. The automobile lamp 100 particularly is a headlamp and includes a light source 10, a reflecting shell 20, a shading portion 30 and a lens 40.

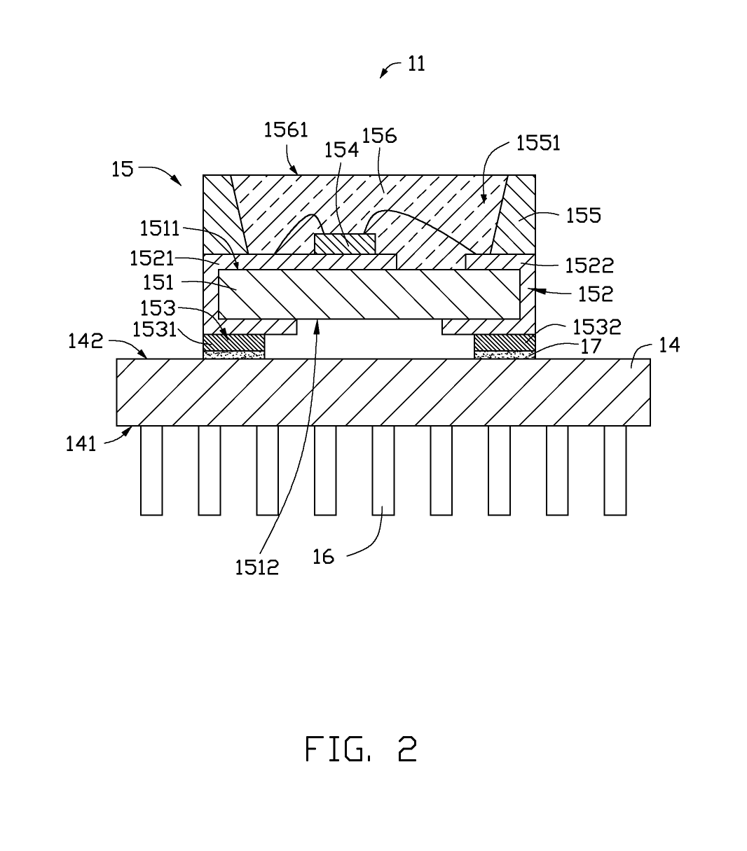

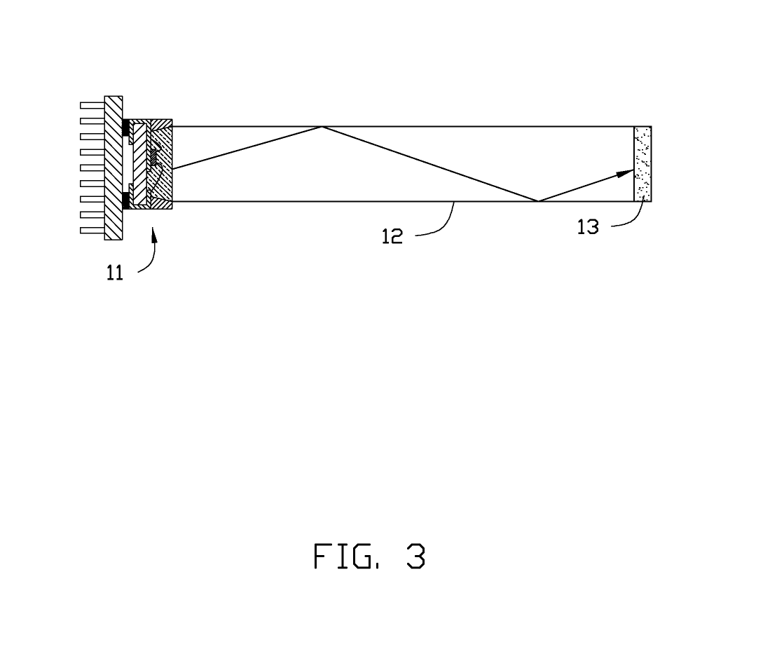

Referring to FIGS. 2 and 3, the light source 10 includes an LED packing structure 11, a fiber 12 with an end 121 coupling with the LED packing structure 11, and a light color converting portion 13 disposed at an opposite end 122 of the fiber 12.

The light color converting portion 13 and the shading portion 30 are arranged between the reflecting shell 20 and the lens 40, and the light color converting portion 10 is located between the reflecting shell 20 and the shading portion 30.

The LED packing structure 11 includes a printed circuit board (PCB) 14 with circuits arranged thereon, at least one LED package 15 and a plurality of fins 16 disposed at two opposite sides of the PCB 14. The LED packing structure 11 is separated from other components of the LED automobile lamp 100.

The PCB 14 includes a bottom surface 141 and a top surface 142 opposite to the bottom surface 141. The fins 16 extend downward from the bottom surface 141 of the PCB 14, for dissipating heat generated by the LED package 15. The LED package 15 is mounted on the top surface 142 by solders 17 and electrically connects with the circuits of the PCB 14.

In this embodiment, the number of the LED package 15 is two. The two LED packages 15 are aligned with each other along a vertical direction. Each LED package 15 includes a substrate 151, an electrode structure 152 disposed on the substrate 151, a pad structure 153 disposed at a periphery of the electrode structure 152, an LED die 154 disposed on the electrode structure 152, a reflector 155 surrounding the LED die 154, and an encapsulation layer 156 encapsulating the LED die 154.

Specifically, the substrate 151 is flat and includes a first surface 1511 and a second surface 1512. The substrate 151 is electrically insulating. The electrode structure 152 includes a first electrode 1521 and a second electrode 1522. Both the first electrode 1521 and the second electrode 1522 extend from the first surface 1511 to the second surface 1512. The pad structure 153 includes a first pad 1531 and a second pad 1532. The first pad 1531 is mounted on a bottom end of the first electrode 1521. The second pad 1532 is mounted on a bottom end of the second electrode 1522. Alternatively, the first pad 1531 and the second pad 1532 can be integrally formed with the first electrode 1521 and the second electrode 1522 respectively.

The LED die 154 is disposed on the first electrode 1521. The LED die 154 electrically connects with the first electrode 1521 and the second electrode 1522 via wire bonding. In this embodiment, the LED die 154 emits blue light. The reflector 155 is disposed on the substrate 151, and the reflector 155 surrounds the LED die 154 to form a recess 1551.

The encapsulation layer 156 is filled in the recess 1551 and encapsulates the LED die 154 therein. The encapsulation layer 156 is made of transparent materials such as transparent resin or silicone. A top surface of the encapsulation layer 156 is coplanar to a top end of the reflector 155 and acts as a light outputting surface 1561 of the LED package 15.

The number of the fiber 12 is equal to that of the LED package 15. In this embodiment, the number of the fibers 12 is two. Each fiber 12 is an optical fiber whereby light can be effectively transmitted by the fiber 12 without loss. Opposite ends 121, 122 of each fiber 12 respectively connect the light outputting surface 1561 of the LED package 15 and the light color converting portion 13, to conduct light emitted by the LED package 15 to the light color converting portion 13.

The light color converting portion 13 is made of transparent materials and contains phosphor therein. The light from the LED die 154 can excite the phosphor in the light color converting portion 13 to form yellow light which mixes the blue light to generate white light. In this embodiment, the light color converting portion 13 contains yellow phosphor therein. Alternatively, the light color converting portion 13 can contain red phosphor and green phosphor to strengthen a color rendering property of the white light. A mixture of light generated by the red phosphor and light generated by the green phosphor due to excitation of the blue light to the red phosphor and green phosphor is yellow light.

The light color converting portion 13 and the shading portion 30 are arranged between the reflecting shell 20 and the lens 40, and the light color converting portion 10 is located between the reflecting shell 20 and the shading portion 30. The light color converting portion 13 and the shading portion 30 are aligned with each other and correspond to centers of the reflecting shell 20 and the lens 40. A size of the light color converting portion 13 is smaller than that of the reflecting shell 20.

Specifically, the light color converting portion 13 directly faces to a middle of the reflecting shell 20. The reflecting shell 20 includes a concave inner surface facing the light color converting portion 13. High reflective materials can be coated at the concave inner surface to reflect and converge the white light from the light color converting portion 13 to the shading portion 30.

The shading portion 30 is located between the light color converting portion 13 and the lens 40. A shape of the shading portion 30 is designed according to a desired luminance shape generated by the LED automobile lamp 100. Specifically, the shading portion 30 includes a side surface (not labeled), and a shape of the side surface is the same as a cut-off line which complies with relevant law and regulations. When the white light from the reflecting shell 20 reaches the shading portion 30, a part of the white light is blocked by the shading portion 30, and the other part of the white light which runs passing the shading portion 30 is regulated to a preset luminance shape with a cut-off line by the side surface of the shading portion 30. That is the shading portion 30 provides a cut-off line to regulate the white light to a preset luminance shape.

The lens 40 is a convex lens. The lens 40 includes an incident surface 41 and a light exit surface 42. The light exit surface 42 is spherical. The white light from shading portion 30 enters the lens via the incident surface 41 and radiates to ambient environment via the light exit surface 42. Alternatively, the lens 40 is an aspheric lens.

Since the LED package 15 is separated from other components in the LED automobile lamp 100, and the phosphor originally contained in the encapsulation layer 156 of light source 10 is transferred to the light color converting portion 13 at one end of the fiber 12, heat generated by the LED package 15 will not influence the stability of the phosphor and the quality of the components around the light color converting portion 13. When the blue light generated by the LED package 15 is delivered to the light color converting portion 13 via the fiber 12, the blue light excites the phosphor in the light color converting portion 13 to form yellow light which mixes with the blue light to generate white light. Thereafter, the white light is reflected by the reflecting shell 20 and converged thereby to reach the shading portion 30, and the white light radiates to ambient environment via regulation of the shading portion 30 and the lens 40. Accordingly, the white light radiates from the LED automobile lamp 100 is uniform in hue. In addition, the LED automobile lamp 100 has a smaller volume since the LED package 15 can be disposed out of the LED automobile lamp 100,

Alternatively, the reflecting shell 20 in the LED automobile lamp 100 can be omitted, and the light color converting portion 13 directly faces the shading portion 30. The light color converting portion 13 can be disposed in the LED automobile lamp 100 away from the LED packing structure 11.

It is to be understood that the above-described embodiments are intended to illustrate rather than limit the disclosure. Variations may be made to the embodiments without departing from the spirit of the disclosure. The above-described embodiments illustrate the scope of the disclosure but do not restrict the scope of the disclosure.

What is claimed is:

1. A light source comprising:
a light emitting diode (LED) packing structure;
a fiber with one end optically coupling with the LED packing structure; and
a light color converting portion disposed at an opposite end of the fiber, the light color converting portion containing phosphor therein;
light emitted by the LED packing structure which has a first color transmitting to the light color converting portion and exciting the phosphor to form light having a second color, the light having a first color and the light having a second color mixing together to generate a light having a third color which is for illuminating a surrounding environment of the light source.

2. The light source of claim 1, wherein the LED packing structure comprises an LED die and an encapsulation layer encapsulating the LED die, the encapsulation layer being made of transparent materials.

3. The light source of claim 2, wherein the encapsulation layer comprises a light outputting surface, the one end of the fiber coupling with the light outputting surface to conduct light emitting out from the light outputting surface to the light color converting portion.

4. The light source of claim 3, wherein the LED die emits blue light, the light color converting portion containing yellow phosphor which is exited by the blue light to generate yellow light.

5. The light source of claim 3, wherein the LED die emits blue light, the light color converting portion containing red phosphor and green phosphor.

6. The light source of claim 1, wherein the fiber is an optical fiber.

7. A light emitting diode (LED) automobile lamp comprising:
a light source, the light source comprising
an LED packing structure;
a fiber with an end coupling with the LED packing structure; and
a light color converting portion disposed at an opposite end of the fiber, the light color converting portion containing phosphor therein, a first light emitted by the LED packing structure transmitting to the light color converting portion and exciting the phosphor to form a second light, the first light and second light mixing together to form a third light having a color different from that of the first light and that of the second light, the third light being configured for illuminating an external environment of the LED automobile lamp;
a lens; and
a shading portion, the shading portion being disposed between the light source and the lens, the third light from the light color converting portion being regulated to a preset luminance shape by the shading portion and radiating out via the lens.

8. The LED automobile lamp of claim 7, wherein the LED packing structure is located out of the LED automobile lamp.

9. The LED automobile lamp of claim 7 further comprising a reflecting shell, the reflecting shell comprising a concave inner surface, the light color converting portion being located between the shading portion and the reflecting shell, the light color converting portion facing a middle of the concave inner surface of the reflecting shell and the third light emitted out the light color converting portion first radiating to the concave inner surface to be reflected thereby and then radiating to the lens via the shading portion.

10. The LED automobile lamp of claim 9, wherein the light color converting portion and the shading portion are aligned with each other and correspond to centers of the reflecting shell and the lens, respectively.

11. The LED automobile lamp of claim 6, wherein the lens is a convex lens, the lens comprising an incident surface and a light exit surface opposite to the incident surface, the third light from the shading portion entering the lens via the incident surface and radiating out via the light exit surface.

12. The LED automobile lamp of claim 11, wherein the light exit surface is spherical surface.

13. The LED automobile lamp of claim 11, wherein the lens is an aspheric lens.

14. The LED automobile lamp of claim 7, wherein the fiber is an optical fiber.

15. The LED automobile lamp of claim 14, wherein the third light is white light.

16. The LED automobile lamp of claim 15, wherein the LED packing structure has a printed circuit board with fins thereon, the fins being configured for dissipating heat of the LED packing structure.
